(19) United States
(12) Patent Application Publication
(10) Pub. No.: US 2013/0200333 A1
(43) Pub. Date: Aug. 8, 2013

(54) SEMICONDUCTOR LIGHT-EMITTING ELEMENT WITH CORTEX-LIKE NANOSTRUCTURES

(71) Applicant: Jer-Liang Yeh, Taichung City (TW)

(72) Inventor: Jer-Liang Yeh, Taichung City (TW)

(21) Appl. No.: 13/567,400

(22) Filed: Aug. 6, 2012

(30) Foreign Application Priority Data
Feb. 3, 2012 (TW) 101103446

(51) Int. Cl. H01L 33/02; B82Y 99/00

(52) U.S. Cl. 257/9; 257/E33.055; 977/762

(57) ABSTRACT

The present invention is to provide a semiconductor light-emitting element. The element comprises a substrate and a nanostructural layer. The nanostructural layer is formed on the substrate and comprises a plurality of void-embedded cortex-like nanostructures, wherein the volumetric porosity of the nanostructural layer is ranged from 30% to 59%. Compared with the prior art, the present invention can not only improve the crystalline quality of epitaxial layers but also enhance the external quantum efficiency (EQE) of the semiconductor light-emitting element.

### BACKGROUND OF THE INVENTION

1. Field of the Invention

The present invention relates to a solid-state light emitting element, and more particularly, to a semiconductor light-emitting element with void-embedded cortex-like nanostructures which has high luminous efficiency.

2. Description of the Prior Art

In recent years, solid-state lighting technology has been widely applied in various fields such as backlight plates, indicator lamps, traffic signal lights, medical equipments, or automobile lighting devices. Light-emitting diodes (LEDs) are the most promising solid-state light sources having advantage of high luminous efficacy, long durability, small size and low driving voltage; besides, LEDs are not only mainly used in the application of backlighting and illumination but also complied with the trend of environment protection and energy saving.

Regarding to the luminous efficiency of LEDs, the external quantum efficiency (EQE) depend on both the internal quantum efficiency (IQE) and the light extraction efficiency; wherein the internal quantum efficiency is the fraction of absorbed photons that are converted to electric current, and related to the properties of LEDs such as the crystal quality of epitaxial layer, or the photonic crystal band.

Nowadays, there has been a great deal of attention to GaN-based light-emitting diodes which can be use to produce ultra-high brightness blue and green LEDs, and sapphire has been the main substrate material of the epitaxial layer for GaN LED. Owing to the mismatch of lattice constants and thermal expansion coefficients between GaN and sapphire, threading dislocations (TDs) are formed in the GaN epitaxial layer; however, the performance of GaN-based LEDs is affected dramatically by these threading dislocations, and these threading dislocations may reduce the internal quantum efficiency by providing a leakage pathway for electron-hole pairs to pass through the active regions.

Accordingly, there are various methods for crystal growth have been developed to improve the threading dislocations, such as epitaxially lateral overgrowth (ELOG), air-bridges lateral epitaxial growth (ABLEG), and nanoscale patterned sapphire substrates (NPSS); wherein, the method of nanoscale patterned sapphire substrates can fabricate the specific nanostructure as the carrier for growing GaN epitaxial films by imprint lithography or etching process, so as to improve the epitaxial quality. However, the flatness between mold and substrate is an important factor during nanoimprint lithography; that is to say, a slightly uneven pressure may cause incomplete contact between the imprinting surfaces, affect the geometric complexity of the nanostructure, or even damage the wafer due to stress concentration. Furthermore, if forming the nanopattern by excimer laser and photomask, the fabricating cost thereof may become prohibitive.

Additionally, owing to the refractive index mismatch between GaN LED and air, the light is constrained within a total reflection critical angle from being extracted; and, the light generated from the epitaxial layer would be total reflected only inside the LED until be absorbed, causing the light to be converted into heat and reducing the luminous efficiency.

Therefore, how to improve the problems described above and meanwhile enhance the luminous efficiency and brightness of LEDs is a primary concern.

### SUMMARY OF THE INVENTION

Accordingly, the present invention provides a high-efficiency semiconductor light-emitting element with void-embedded cortex-like nanostructures, fabricated on a patterned sapphire substrate by metal-organic chemical vapor deposition (MOCVD) and inductively-coupled plasma reactive ion etch (ICP-RIE).

The semiconductor light-emitting element of the invention comprises a substrate and a nanostructural layer; the nanostructural layer is formed on the substrate and comprises a plurality of void-embedded cortex-like nanostructures, wherein the volumetric porosity of the nanostructural layer is ranged from 30% to 59%. Moreover, the material of the substrate can be selected from sapphire, silicon carbide (SiC), gallium nitride (GaN), aluminum nitride (AlN), or aluminum gallium nitride (GaAlN).

More specifically, the void-embedded cortex-like nanostructures are distributed on the nanostructural layer with a density of 10¹⁰ cm⁻², a spacing of 50-150 nm, and a depth of 80-150 nm. Furthermore, the nanostructural layer further comprises a buffer layer having a plurality of pits produced by threading dislocations (TDs), wherein the plurality of pits are distributed on the buffer layer with a density of 10⁷/cm² to 10⁸/cm², and the buffer layer has a root-mean-square surface roughness ranged from 0.3 nm to 0.4 nm.

Compared with the prior art, the semiconductor light-emitting element with void-embedded cortex-like nanostructures of the present invention has a new morphology that can not only improve the crystalline quality of epitaxial layers but also enhance the external quantum efficiency (EQE) of the semiconductor light-emitting element. In addition, the semiconductor light-emitting element is patterned by natural lithography, thus without the implementation of an expensive semiconductor mask, the fabricating method of the present invention is cost-effective.

Many other advantages and features of the present invention will be further understood by the detailed description and the accompanying sheet of drawings.

### BRIEF DESCRIPTION OF THE APPENDED DRAWINGS

FIG. 1 is a schematic diagram of a semiconductor light-emitting element of the invention.

FIG. 2 is a cross-section view of a semiconductor light-emitting element of the invention.

FIG. 3(a) is an atomic force microscopy image showing the morphology of the nanostructural layer of the invention.

FIG. 3(b) is an atomic force microscopy image showing the morphology of the buffer layer of the invention.

FIG. 3(c) is an atomic force microscopy image showing the morphology of a conventional buffer layer.

FIG. 4 is a transmission electron microscopy image showing the cross-section of the nanostructural layer of the invention.

FIG. 5 is a flowchart illustrating a fabricating method of the semiconductor light-emitting element according to the invention.

To facilitate understanding, identical reference numerals have been used, where possible to designate identical elements that are common to the figures.

### DETAILED DESCRIPTION OF THE INVENTION

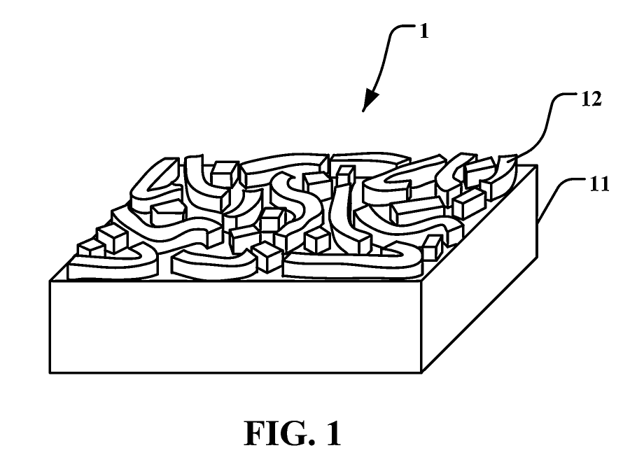

Please refer to FIG. 1. FIG. 1 is a schematic diagram of a semiconductor light-emitting element of the invention. As shown in FIG. 1, the invention discloses a semiconductor light-emitting element 1 with void-embedded cortex-like nanostructures. The semiconductor light-emitting element 1 comprises a substrate 11 and a nanostructural layer 12, and the nanostructural layer 12 is formed on the substrate 11 and comprises a plurality of cortex-like nanostructures with voids 14 embedded. In actual application, the semiconductor light-emitting element 1 can be a light emitting diode, and the substrate 11 can be, but not limited to sapphire, silicon carbide (SiC), gallium nitride (GaN), aluminum nitride (AlN), or aluminum gallium nitride (GaAlN).

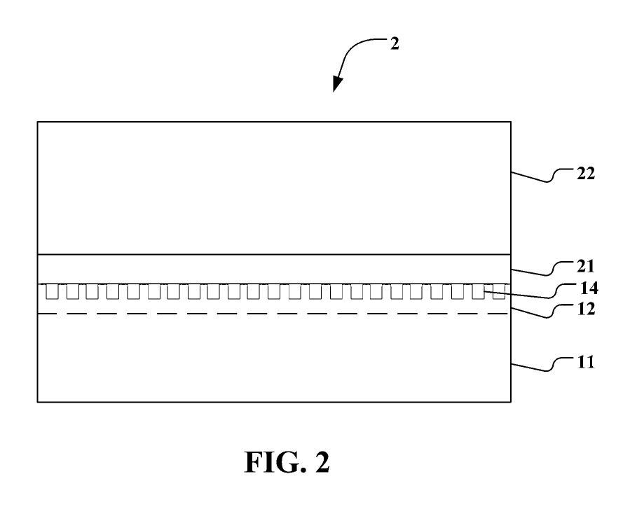

Please refer to FIG. 2. FIG. 2 is a cross-section view of a semiconductor light-emitting element of the invention. As shown in FIG. 2, the semiconductor light-emitting element 1 of the present invention further comprises a buffer layer 21 and an epitaxial layer 22. The buffer layer 21 can be formed on the nanostructural layer 12 by metal-organic chemical vapor deposition (MOCVD), and the epitaxial layer 22 is formed on the buffer layer 21. To be noticed, owing to the threading dislocations (TDs), there are pluralities of pits produced and distributed on the buffer layer 21 with a density of 10⁷/cm² to 10⁸/cm², and the buffer layer 21 has a root-mean-square surface roughness ranged from 0.3 nm to 0.4 nm. Additionally, the epitaxial layer 22 can comprise including, but not limited to n-type semiconductor layer, p-type semiconductor layer, multiple quantum well (MQW), and electron blocking layer.

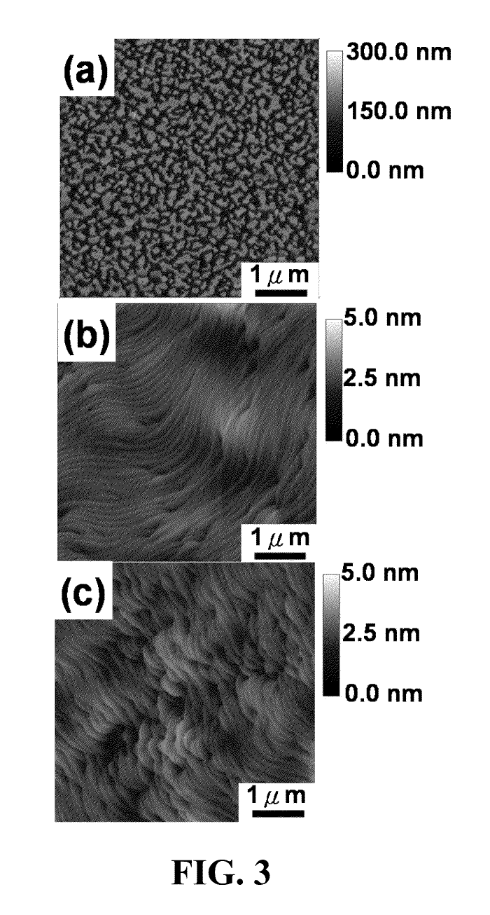

Please refer to FIG. 3(a). FIG. 3(a) is an atomic force microscopy image showing the morphology of the nanostructural layer of the invention. In actual application, when the substrate 11 is sapphire and the buffer layer 21 is GaN, the morphology of the nanostructural layer 12 can be clearly revealed by atomic force microscopy (AFM) as shown in FIG. 3(a); wherein the volumetric porosity of the nanostructural layer 12 is ranged from 30% to 59%, and there are pluralities of void-embedded cortex-like nanostructures distributed on the nanostructural layer 12 with a density of 10¹⁰ cm⁻², a spacing of 50-150 nm, and a depth of 80-150 nm.

Please refer to FIGS. 3(b) and 3(c). FIGS. 3(b) and 3(c) are the atomic force microscopy images showing the morphology of the buffer layer in the present invention and in the prior art respectively. Over the scan area of 5×5 μm2, the pluralities of pits on the surface of the buffer layer 21 are observed by AFM as shown in FIGS. 3(b) and 3(c). Obviously, the pit density is in the range of 10⁷ to 10⁸ cm⁻² for the buffer layer 21 grown on the semiconductor light-emitting element 1 with void-embedded cortex-like nanostructures, smaller than that grown on the conventional sapphire substrates by two orders (i.e., 10⁹ to 10¹⁰ cm², as shown in FIG. 3(c)). Therefore, the nanostructural layer 12 of the invention can reduce the amount of the pits produced by the threading dislocations (TDs) effectively, and further to improve the crystalline quality of epitaxial layers 22.

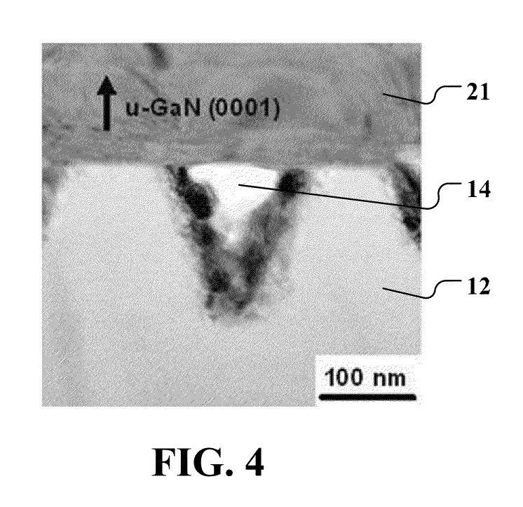

Please refer to FIG. 4. FIG. 4 is a transmission electron microscopy image showing the cross-section of the nanostructural layer of the invention. In this embodiment, when sapphire is used as the substrate 11 and GaN is used as the buffer layer 21, the voids 14 formed by lateral epitaxial overgrowth are formed beneath the buffer layer 21 and embedded within the nanostructures, as shown in FIG. 4; wherein the refractive index of the GaN buffer layer 21 is 2.45, the refractive index of the sapphire substrate 11 is 1.78, the refractive index of the voids 14 is 1 (the same as air), and the refractive index of the nanostructural layer 12 is ranged between 1 and 1.78. With various refractive index in the semiconductor light-emitting element 1, the light generated from the epitaxial layers 22 can be constrained to reflect in the top direction between the buffer layer 21 and the nanostructural layer 12, and thereby further decreasing the total reflection.

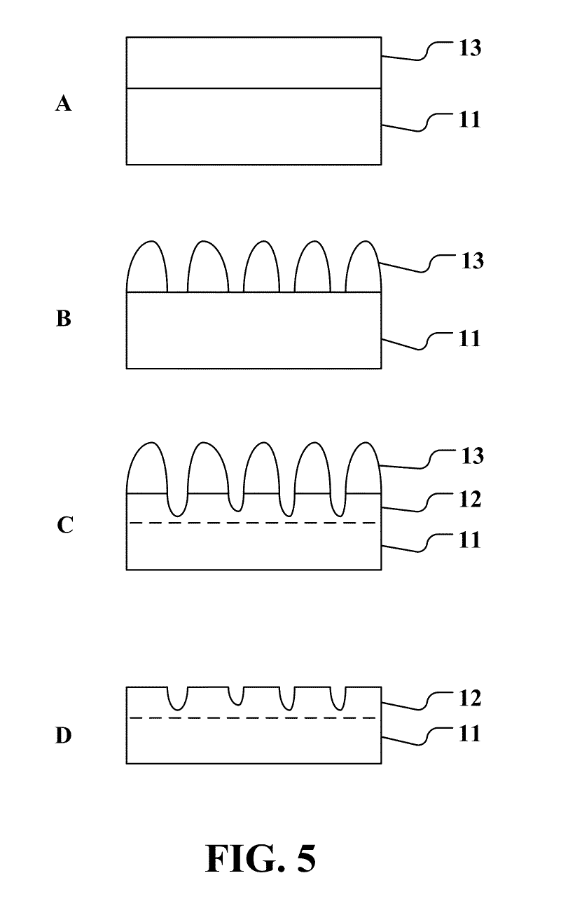

Please refer to FIG. 5. FIG. 5 is a flowchart illustrating a fabricating method of the semiconductor light-emitting element according to the invention. As shown in FIG. 5, the fabricating method of the present invention comprises steps (a) to (d), wherein the step (a) is to provide a substrate 11 and deposit a polysilicon thin-film as a mask layer 13 on the substrate 11. The material of the substrate 11 can be selected from sapphire, silicon carbide (SiC), gallium nitride (GaN), aluminum nitride (AlN), or aluminum gallium nitride (GaAlN). The step (b) is soaking the substrate 11 in an etching solution so as to texture the surface of the mask layer 13 and form a hard mask. To be noticed, the etching solution is in a proportion of mixed acid solution: DI water=1:5, wherein the mixed acid solution includes but not limited to chrome acid, copper nitrate, nitric acid, hydrofluoric acid and acetic acid. After forming the hard mask, the step (c) is etching the substrate 11 vertically by inductively coupled plasma-reactive ion etching (ICP-RIE), so as to fabricate the nanostructural layer 12 in the present invention. Subsequently, step (d) is removing the hard mask of the mask layer 13 on the substrate 11 by a hot KOH solution. Accordingly, the semiconductor light-emitting element 1 with void-embedded cortex-like nanostructures can be fabricated by repeating the above steps.

Compared with the prior art, the semiconductor light-emitting element with void-embedded cortex-like nanostructures of the present invention has an emitting wavelength of 438 nm, and the external quantum efficiency (EQE) thereof can be enhanced to 58.3%, increased 2.4-fold higher than that of the prior art. Furthermore, the present invention has a new morphology that can not only improve the crystalline quality of epitaxial layers but also generate a void-embedded nanostructural layer to enhance light extraction. In addition, the semiconductor light-emitting element is patterned by natural lithography, thus without the implementation of an expensive semiconductor mask, the fabricating method of the present invention is cost-effective.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor light-emitting element, comprising:
a substrate; and
a nanostructural layer, formed on the substrate and comprising a plurality of void-embedded cortex-like nanostructures;
wherein, the volumetric porosity of the nanostructural layer is ranged from 30% to 59%.

2. The semiconductor light-emitting element of claim 1, wherein the density of the void-embedded cortex-like nanostructures is at least 10¹⁰/cm².

3. The semiconductor light-emitting element of claim 1, wherein the spacing of the void-embedded cortex-like nanostructures is ranged from 50 to 150 nm.

4. The semiconductor light-emitting element of claim 1, wherein the depth of the void-embedded cortex-like nanostructures is ranged from 80 to 150 nm.

5. The semiconductor light-emitting element of claim 1, further comprising a buffer layer formed on the nanostructural layer.

6. The semiconductor light-emitting element of claim 5, wherein the buffer layer has a plurality of pits produced by threading dislocations.

7. The semiconductor light-emitting element of claim 5, wherein the plurality of pits are distributed on the buffer layer with a density of 10²/cm² to 10⁸/cm².

8. The semiconductor light-emitting element of claim 5, wherein the buffer layer has a root-mean-square surface roughness ranged from 0.3 nm to 0.4 nm.

9. The semiconductor light-emitting element of claim 1, wherein the material of the substrate is sapphire.
